(19) United States
(12) Patent Application Publication
(10) Pub. No.: US 2014/0117405 A1
(43) Pub. Date: May 1, 2014

(54) SEMICONDUCTOR DEVICE

(71) Applicant: SAMSUNG ELECTRO-MECHANICS CO., LTD., Suwon (KR)

(72) Inventors: Jaehoon PARK, Suwon (KR); Chang Su JANG, Suwon (KR); In Hyuk SONG, Suwon (KR); Kee Ju UM, Suwon (KR); Dong Soo SEO, Suwon (KR)

(73) Assignee: SAMSUNG ELECTRO-MECHANICS CO., LTD., Suwon (KR)

(21) Appl. No.: 13/746,616

(22) Filed: Jan. 22, 2013

(30) Foreign Application Priority Data
Oct. 29, 2012 (KR) 10-2012-0120725

(51) Int. Cl. H01L 29/739

(52) U.S. Cl. CPC H01L 29/7395
USPC 257/139

(57) ABSTRACT

There is provided a semiconductor device including: a first semiconductor region having a first conductivity type; a second semiconductor region having a second conductivity type and formed on one surface of the first semiconductor region; a third semiconductor region having a first conductivity type and formed on one surface of the second semiconductor region; a gate electrode formed in a trench penetrating through the second semiconductor region and the third semiconductor region to reach an interior of the first semiconductor region; and a hole injection unit formed between the gate electrode and the first semiconductor region.

### CROSS-REFERENCE TO RELATED APPLICATIONS

This application claims the priority of Korean Patent Application No. 10-2012-0120725 filed on Oct. 29, 2012, in the Korean Intellectual Property Office, the disclosure of which is incorporated herein by reference.

### BACKGROUND OF THE INVENTION

1. Field of the Invention

The present invention relates to a semiconductor device.

2. Description of the Related Art

Recently, a decrease in power consumed by power converters has been demanded. Therefore, research into technology for decreasing power consumption in a power semiconductor device playing a central role among power converters has been actively conducted.

In particular, research into an insulated gate bipolar transistor (IGBT), among power semiconductor devices, has been actively conducted. An IGBT may decrease turned-on voltage and increase current density through a conductivity modulation effect.

In the case in which current density increases, a saturation voltage (V_{ce, sat}) may be decreased. In addition, in the case in which current density increases, a chip size may be significantly decreased at the same current rate, such that chip manufacturing costs may be decreased.

IGBTs may include a planar type IGBT, a trench type IGBT, and the like. The planar type IGBT has a structure in which a gate electrode is formed on a wafer surface. The trench type IGBT has a structure in which an oxide film is interposed in a trench formed downwardly of a wafer surface in a vertical direction and a gate electrode is buried therein.

Since the trench type IGBT may have channels formed in both inner walls of the trench, it has higher channel density than that of a planar type IGBT. Therefore, the trench type IGBT may increase a conductivity modulation effect.

Therefore, research into IGBTs, in particular, trench type IGBTs, has been actively conducted.

However, in the case of a general IGBT, a p-n junction below the IGBT should be turned on. That is, the IGBT may only be operated in the case in which voltage having a threshold value or larger is applied to the IGBT. Therefore, the IGBT may not be used in a voltage region having a voltage equal to a threshold value or less.

### RELATED ART DOCUMENT

(Patent Document 1) Japanese Patent Laid-Open Publication No. JP 2001-313393

### SUMMARY OF THE INVENTION

An aspect of the present invention provides an insulated gate bipolar transistor (IGBT) capable of being operated without limitation of a threshold value.

Another aspect of the present invention provides a semiconductor device having improved current density.

According to an aspect of the present invention, there is provided a semiconductor device including: a first semiconductor region having a first conductivity type; a second semiconductor region having a second conductivity type and formed on one surface of the first semiconductor region; a third semiconductor region having a first conductivity type and formed on one surface of the second semiconductor region; agate electrode formed in a trench penetrating through the second semiconductor region and the third semiconductor region to reach an interior of the first semiconductor region; and a hole injection unit formed between the gate electrode and the first semiconductor region.

The hole injection unit may allow holes to be injected into the first semiconductor region when a gate voltage is applied.

The hole injection unit may form a heterojunction with the first semiconductor region.

The semiconductor device may further include an insulating layer formed between the gate electrode and first to third semiconductor regions.

The first semiconductor region may include a first conductivity type buffer layer having a higher impurity concentration than that of the first semiconductor region.

The first semiconductor region may include a first conductivity type body layer having an upper surface contacting the second semiconductor region and a higher impurity concentration than that of the first semiconductor region.

The first conductivity type may be a n-type, and the second conductivity type may be a p-type.

The semiconductor device may further include: an interlayer insulating film formed over the trench; and an emitter electrode formed on the interlayer insulating film.

The emitter electrode may conductively contact the third semiconductor region and the second semiconductor region.

The semiconductor device may further include a collector electrode formed on the other surface of the first semiconductor region.

According to another aspect of the present invention, there is provided a semiconductor device including: a first semiconductor region having a first conductivity type; a second semiconductor region having a second conductivity type and formed on one surface of the first semiconductor region; a third semiconductor region having a first conductivity type and formed on one surface of the second semiconductor region; agate electrode formed in a trench penetrating through the second semiconductor region and the third semiconductor region to reach an interior of the first semiconductor region; and a hole injection unit disposed under the gate electrode and forming a heterojunction with the first semiconductor region.

The hole injection unit may be formed between the gate electrode and the first semiconductor region.

The hole injection unit may allow holes to be injected into the first semiconductor region when a gate voltage is applied.

According to another aspect of the present invention, there is provided a semiconductor device including: a first semiconductor region having a first conductivity type; a second semiconductor region having a second conductivity type and formed on one surface of the first semiconductor region; a third semiconductor region having a first conductivity type and formed on one surface of the second semiconductor region; agate electrode formed in a trench penetrating through the second semiconductor region and the third semiconductor region to reach an interior of the first semiconductor region; and a hole injection unit disposed the gate electrode and allowing holes to be injected into the first semiconductor region.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of a trench type insulated gate bipolar transistor (IGBT);

FIG. 2 is a cross-sectional view schematically showing a trench type IGBT according to an embodiment of the present invention;

FIGS. 3A and 3B is a view showing a band gap on a junction surface between a hole injection unit and a first semiconductor region according to the embodiment of the present invention;

FIG. 4 is a view showing a relationship between a collector-emitter voltage (V_{cE}) and a collector current (Ic) in the IGBT according to the embodiment of the present invention;

FIG. 5 is a cross-sectional view schematically showing an IGBT according to another embodiment of the present invention; and

FIG. 6 is a cross-sectional view schematically showing an IGBT according to another embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

A power switch may be implemented by any one of a power metal oxide semiconductor field effect transistor (MOSFET), an insulated gate bipolar transistor (IGBT), various types of thyristors, and the like. Most novel technologies disclosed herein are described based on the IGBT. However, various embodiments of the present invention disclosed herein are not limited to the IGBT, but may be applied to various types of power switch technology including the power MOSFET and various types of thyristors in addition to a diode. In addition, in various embodiments of the present invention, it is described that the IGBT includes specific p-type and n-type regions. However, the embodiments of the present invention may be similarly applied to devices including various regions having opposite conductivity types, as disclosed herein.

In addition, the terms n-type and p-type, as used herein, may be defined as a first conductivity type, or a second conductivity type. Meanwhile, the first conductivity type, and the second conductivity type may mean different conductivity types.

Further, in general, ‘+’ refers to a high concentration doped state, and ‘−’ refers to a low concentration doped state.

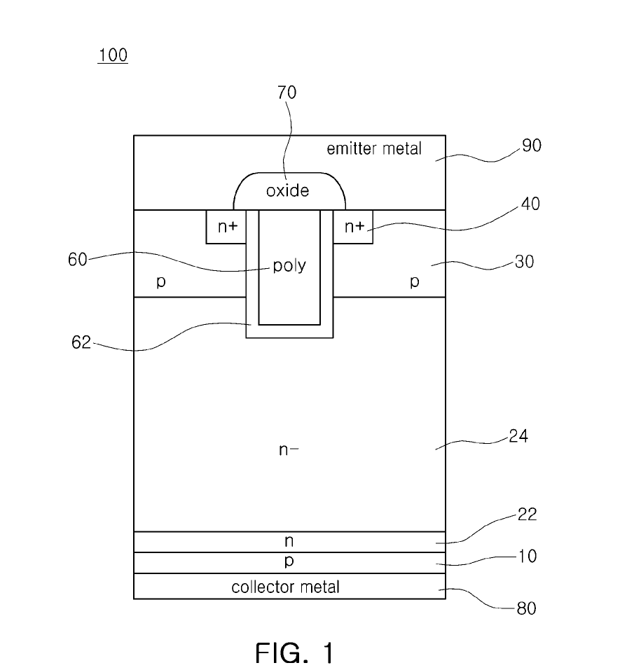

FIG. 1 is a cross-sectional view of a trench type IGBT.

As shown in FIG. 1, a general trench type IGBT 100 may include a p-type semiconductor region 10, an n-type semiconductor region 22 formed on one surface of the p-type semiconductor region 10, an n-type semiconductor region 24 formed on one surface of the n-type semiconductor region 22 and doped at a low concentration, a p-type semiconductor region 30 formed on one surface of the n-type semiconductor region 24 doped at a low concentration, an n-type semiconductor region 40 formed on one surface of the p-type semiconductor region 30 and doped at a high concentration.

In addition, the trench type IGBT 100 may include a gate electrode 60 present in a trench formed to penetrate through the p-type semiconductor region 30 and the n-type semiconductor region 40 doped at a high concentration in a depth direction to reach the n-type semiconductor region 24 doped at a low concentration.

In addition, the trench type IGBT 100 may include an insulating layer 62 formed between the gate electrode 60 and an inner side surface of the trench.

That is, the trench type IGBT 100 may include the insulating layer 62 formed between the gate electrode 60 and the n-type semiconductor region 40 doped at a high concentration, the gate electrode 60 and the p-type semiconductor region 30, and the gate electrode 60 and the n-type semiconductor region 24 doped at a low concentration.

An interlayer insulating film 70 coated over the trench may insulate an emitter electrode 90 and the gate electrode 60 from each other.

The emitter electrode 90 formed on the interlayer insulating film 70 may be formed so as to commonly conductively contact the n-type semiconductor region 40 doped at a high concentration and the p-type semiconductor region 30 by using an open window installed in the interlayer insulating film 70.

In addition, a collector electrode 80 may be formed on the other surface of the p-type semiconductor region 10.

In order to turn on the trench type IGBT of FIG. 1, a voltage having a predetermined value or higher needs to be applied to the gate electrode 60 in a state in which a voltage applied to the collector electrode 80 is higher than a voltage applied to the emitter electrode 90.

An electrical charge is accumulated in the gate electrode 60 by the voltage as described above, and at the same time, the insulating layer 62 as a gate oxide film is interposed between the gate electrode 60 and the p-type semiconductor region 30, such that an n-type inversion channel (not-shown) is formed on a surface of the p-type semiconductor region 30 facing the gate electrode 60.

Through the n-type inversion channel, electrons are injected into the n-type semiconductor region 24 doped at a low concentration from the n-type semiconductor region 40 doped at a high concentration. A collector junction (junction between the n-type semiconductor region 22 and the p-type semiconductor region 10) is forward biased by the injected electrons, and holes are introduced from the p-type semiconductor region 10 in an upward direction, such that the trench type IGBT is turned on.

Meanwhile, when the collector junction is forward biased, a voltage drop occurs due to a p-n junction.

A voltage drop value between the collector electrode and the emitter electrode in such a turned-on state corresponds to a turn-on voltage.

If the IGBT is converted from a turned-on state to a turned-off state, the voltage applied to the gate electrode 60 needs to be a predetermined value or less.

Through the above-mentioned process, the electrical charge accumulated in the gate electrode 60 is discharged to a gate driving circuit through a gate resistor. Here, since the n-type inversion channel is converted into the p-type inversion channel, a path through which the electrons pass is not present. Accordingly, the electrons are not supplied to the n-type semiconductor region 24 doped at a low concentration. Therefore, since the holes are not introduced from the p-type semiconductor region 10, the electrons and the holes accumulated in the n-type semiconductor region 24 doped at a low concentration are discharged to the collector electrode 80 and the emitter electrode 90, or recombined with each other. Therefore, a current disappears, and the IGBT is turned-off.

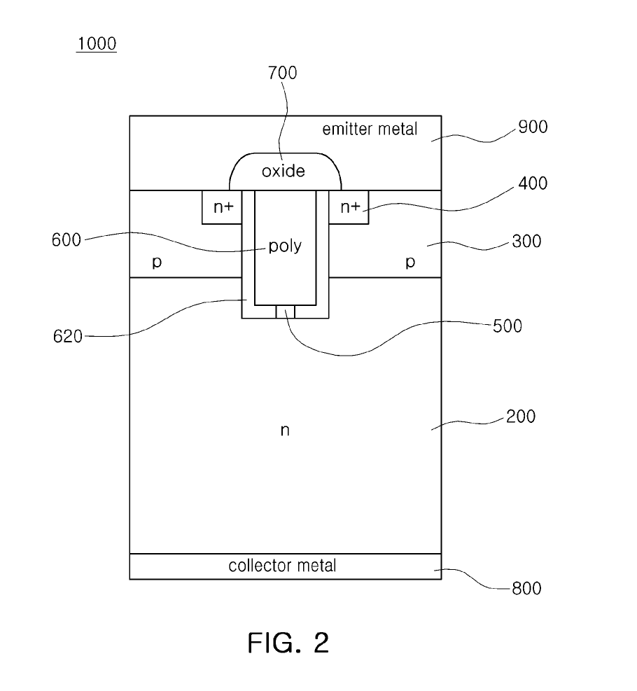

FIG. 2 is a cross-sectional view schematically showing a trench type IGBT according to an embodiment of the present invention.

Referring to FIG. 2, a trench type IGBT 1000 may include an n-type semiconductor region 200 doped at a low concentration, a p-type semiconductor region 300 formed on one surface of the n-type semiconductor region 200 doped at a low concentration, and an n-type semiconductor region 400 formed on one surface of the p-type semiconductor region 300 and doped at a high concentration.

Meanwhile, for convenience of explanation, the n-type semiconductor region 200 doped at a low concentration may be defined as a first semiconductor region. In addition, the p-type semiconductor region 300 may be defined as a second semiconductor region. In addition, the n-type semiconductor region 400 may be defined as a third semiconductor region.

In addition, the trench type IGBT 1000 may include a gate electrode 600 present in a trench formed to penetrate through the p-type semiconductor region 300 and the n-type semiconductor region 400 doped at a high concentration in a depth direction to reach the n-type semiconductor region 200 doped at a low concentration while.

In addition, the trench type IGBT 1000 may include an insulating layer 620 formed between the gate electrode 600 and an inner side surface of the trench.

That is, the trench type IGBT 1000 may include the insulating layer 620 formed between the gate electrode 600 and the n-type semiconductor region 400 doped at a high concentration, the gate electrode 600 and the p-type semiconductor region 300, and the gate electrode 600 and the n-type semiconductor region 200 doped at a low concentration.

An interlayer insulating film 700 coated over the trench may insulate an emitter electrode 900 and the gate electrode 600 from each other.

The emitter electrode 900 formed on the interlayer insulating film 700 may be formed so as to commonly conductively contact the n-type semiconductor region 400 doped at a high concentration and the p-type semiconductor region 300 by using an open window to be installed in the interlayer insulating film 700.

In addition, a collector electrode 800 may be formed on the other surface of the n-type semiconductor region 200 doped at a low concentration.

According to the embodiment of the present invention, a hole injection unit 500 may be formed between the gate electrode 600 and the n-type semiconductor region 200 defined as the first semiconductor region (hereinafter, referred to as the first semiconductor region 200).

The hole injection unit 500 may have a surface on which the gate electrode 600 comes into contact therewith. In addition, the hole injection unit 500 may have a surface on which the first semiconductor region 200 comes into contact therewith. Further, the hole injection unit 500 may have a surface on which the insulating layer 620 comes into contact therewith.

The hole injection unit 500 may form a heterojunction with the first semiconductor region 200.

A band gap region of the hole injection unit 500 may be formed in a band gap region of the first semiconductor region 200.

For example, the lowermost energy level of a conduction band of the hole injection unit 500 may be lower than that of a material forming the first semiconductor region 200. In addition, the uppermost energy level of a valence band of the hole injection unit 500 is higher than that of a material forming the first semiconductor region 200.

According to the embodiment of the present invention, when a predetermined voltage is applied to a space between the collector electrode 800 and the emitter electrode 900, a predetermined voltage is applied to the gate electrode 600, the hole injection unit 500 may inject holes into the first semiconductor region 200.

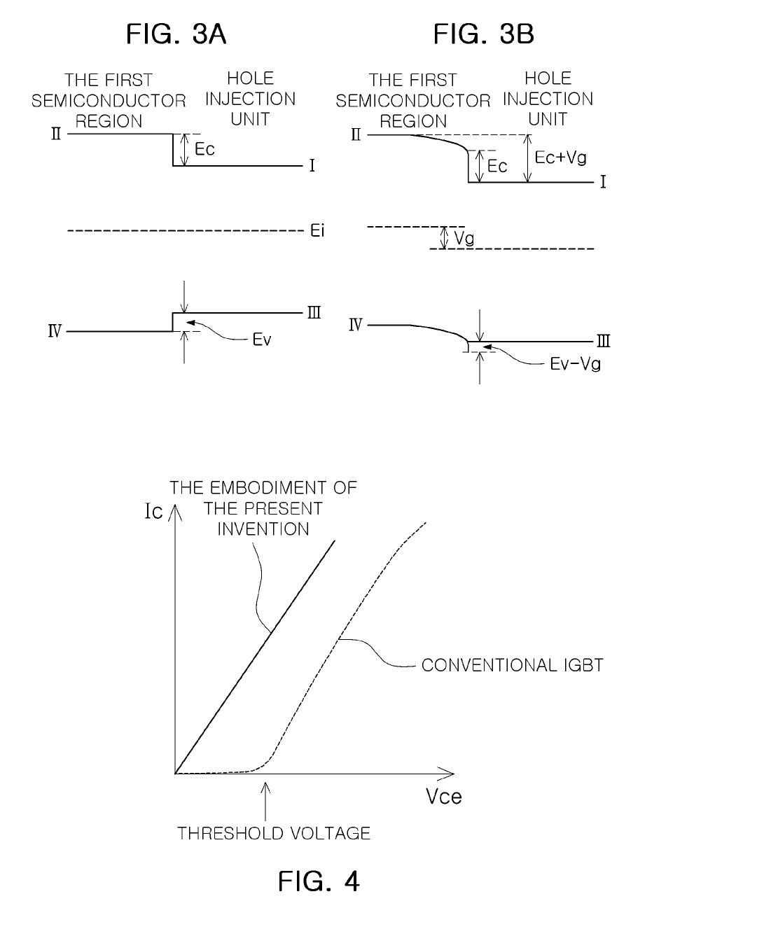

FIG. 3 is a view showing a band gap on a junction surface between the hole injection unit 500 and the first semiconductor region 200 according to the embodiment of the present invention.

FIG. 3A shows the band gap on the junction surface between the hole injection unit 500 and the first semiconductor region 200 when a voltage is not applied.

Referring to FIG. 3A, the lowermost energy level I of the conduction band of the hole injection unit 500 is lower than the lowermost energy level II of the conduction band of the material forming the first semiconductor region 200. Here, a difference between two energy levels (I and II) is defined as Ec.

In addition, the uppermost energy level III of a valence band of the hole injection unit 500 may be higher than the uppermost energy level IV of the valence band of the material configuring the first semiconductor region 200. Here, a difference between two energy levels (III and IV) is defined as Ev.

FIG. 3B shows the band gap on the junction surface between the hole injection unit 500 and the first semiconductor region 200 when a voltage is applied.

As shown in FIG. 3B, the band gap of the hole injection unit 500 may be decreased overall due to the application of voltage. For example, the lowermost energy level I of the conduction band and the uppermost energy level III of the valence band of the hole injection unit 500 may be respectively lowered by a predetermined magnitude Vg.

Referring to FIG. 3B, the difference between the lowermost energy level I of the conduction band of the hole injection unit 500 and the lowermost energy level II of the conduction band of the material forming the first semiconductor region 200 may be increased as compared to the case before the voltage is applied. That is, the difference between two energy levels (I and II) may be defined as a sum of Ec and Vg, that is, Ec+Vg.

In addition, the difference between the uppermost energy level III of a valence band of the hole injection unit 500 and the uppermost energy level IV of a material forming the first semiconductor region 200 may be decreased as compared to the case before the voltage is applied. That is, the difference between two energy levels (III and IV) may be defined as Ev-Vg.

Referring to the band gap shown in FIG. 3B, it may be appreciated that when the voltage is applied, the injection of holes from the hole injection unit 500 to the first semiconductor region 200 is further suppressed.

In addition, referring to the band gap shown in FIG. 3B, it may be appreciated that when the voltage is applied, the injection of holes from the hole injection unit 500 to the first semiconductor region 200 is further activated.

FIG. 4 is a view showing a relationship between a collector-emitter voltage (V_{CE}) and a collector current (Ic) in the IGBT according to the embodiment of the present invention.

In the IGBT according to the related art, electrons are injected from an n+ type emitter region into an n-type drift layer. In addition, since the injected electrons are required to forward bias the collector junction, the collector current Ic may flow in the case in which a voltage having a threshold value or larger is applied to the IGBT.

According to the embodiment of the present invention, even though the voltage having the threshold value or larger is not applied, the hole injection unit 500 may inject the holes into the first semiconductor region 200 by the heterojunction between the hole injection unit 500 and the first semiconductor region 200.

Therefore, as shown in FIG. 4, the collector current Ic may be increased from a point at which the a collector-emitter voltage V_{CE} is 0 or larger. That is, according to the present invention, the voltage does not drop at the p-n junction of the IGBT according to the related art.

Meanwhile, according to the embodiment of the present invention, the IGBT may be driven using a current higher as compared with the case of a MOSFET in a low-voltage region due to the holes directly supplied from the hole injection unit 500.

In addition, an operation voltage range of the IGBT may be improved due to the holes directly supplied from the hole injection unit 500.

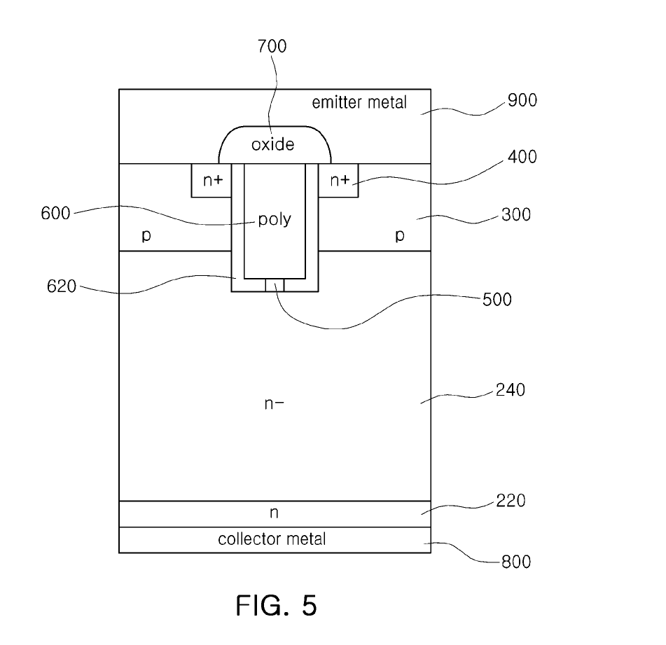

FIG. 5 is a cross-sectional view schematically showing an IGBT according to another embodiment of the present invention.

Referring to FIG. 5, the first semiconductor region 200 may include an n-type semiconductor region 240 doped at a low concentration, and an n-type buffer layer 220 having a relatively higher impurity concentration than that of the n-type semiconductor region.

The buffer layer 220 may be formed under the n-type semiconductor region 240.

The buffer layer 220 may provide a field stop function. Therefore, in the IGBT according to the embodiment of the present invention, the n-type semiconductor region 240 doped at a low concentration may be thinly formed under the same internal pressure conditions as compared to the case without the buffer layer.

In addition, a turn-on voltage may be further decreased in the IGBT according to the present embodiment.

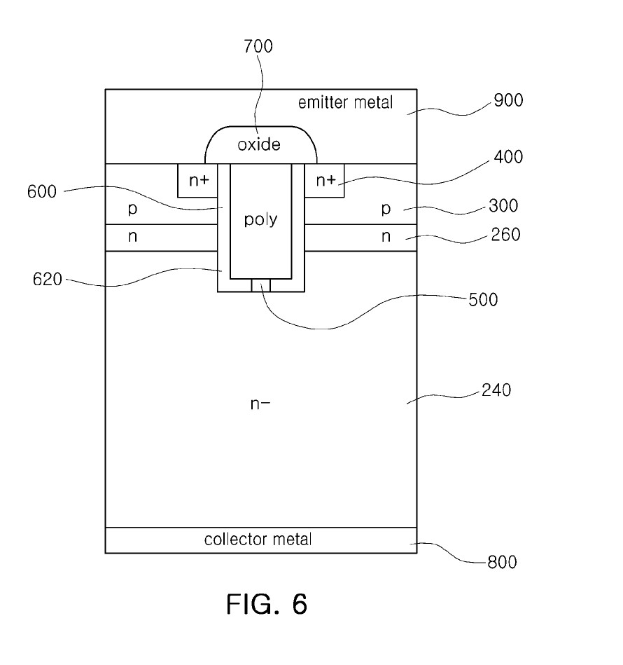

FIG. 6 is a cross-sectional view schematically showing an IGBT according to another embodiment of the present invention.

Referring to FIG. 6, the first semiconductor region 200 may include the n-type semiconductor region 240 doped at a low concentration, and an n-type body layer 260 having a relatively higher impurity concentration than that of the n-type semiconductor region.

The body layer 260 may be formed on the n-type semiconductor region 240.

In this case, the leakage of holes to the emitter electrode may be limited due to repulsion caused by donor ions of the n-type body layer 260, the holes being introduced from the n-type semiconductor region 240 doped at a low concentration to the p-type semiconductor region 300.

Therefore, due to the above-mentioned configuration, a carrier concentration under the trench around the emitter may be increased and the turn-on voltage may be further decreased.

As set forth above, according to the embodiment of the present invention, the IGBT capable of being operated without limitation of the threshold value may be provided.

In addition, according to the embodiment of the present invention, the semiconductor device having improved current density may be provided.

While the present invention has been shown and described in connection with the embodiments, it will be apparent to those skilled in the art that modifications and variations can be made without departing from the spirit and scope of the invention as defined by the appended claims.

What is claimed is:

1. A semiconductor device comprising:
a first semiconductor region having a first conductivity type;
a second semiconductor region having a second conductivity type and formed on one surface of the first semiconductor region;
a third semiconductor region having a first conductivity type and formed on one surface of the second semiconductor region;
a gate electrode formed in a trench penetrating through the second semiconductor region and the third semiconductor region to reach an interior of the first semiconductor region; and
a hole injection unit formed between the gate electrode and the first semiconductor region.

2. The semiconductor device of claim 1, wherein the hole injection unit allows holes to be injected into the first semiconductor region when a gate voltage is applied.

3. The semiconductor device of claim 1, wherein the hole injection unit forms a heterojunction with the first semiconductor region.

4. The semiconductor device of claim 1, further comprising an insulating layer formed between the gate electrode and first to third semiconductor regions.

5. The semiconductor device of claim 1, wherein the first semiconductor region includes a first conductivity type buffer layer having a higher impurity concentration than that of the first semiconductor region.

6. The semiconductor device of claim 1, wherein the first semiconductor region includes a first conductivity type body layer having an upper surface contacting the second semiconductor region and a higher impurity concentration than that of the first semiconductor region.

7. The semiconductor device of claim 1, wherein the first conductivity type is an n-type, and the second conductivity type is a p-type.

8. The semiconductor device of claim 1, further comprising:
an interlayer insulating film formed over the trench; and
an emitter electrode formed on the interlayer insulating film.

9. The semiconductor device of claim 8, wherein the emitter electrode conductively contacts the third semiconductor region and the second semiconductor region.

10. The semiconductor device of claim 1, further comprising a collector electrode formed on the other surface of the first semiconductor region.

11. A semiconductor device comprising:
a first semiconductor region having a first conductivity type;
a second semiconductor region having a second conductivity type and formed on one surface of the first semiconductor region;
a third semiconductor region having a first conductivity type and formed on one surface of the second semiconductor region;
a gate electrode formed in a trench penetrating through the second semiconductor region and the third semiconductor region to reach an interior of the first semiconductor region; and
a hole injection unit disposed under the gate electrode and forming a heterojunction with the first semiconductor region.

12. The semiconductor device of claim 11, wherein the hole injection unit is formed between the gate electrode and the first semiconductor region.

13. The semiconductor device of claim 11, wherein the hole injection unit allows holes to be injected into the first semiconductor region when a gate voltage is applied.

14. A semiconductor device comprising:
a first semiconductor region having a first conductivity type;
a second semiconductor region having a second conductivity type and formed on one surface of the first semiconductor region;
a third semiconductor region having a first conductivity type and formed on one surface of the second semiconductor region;
a gate electrode formed in a trench penetrating through the second semiconductor region and the third semiconductor region to reach an interior of the first semiconductor region; and
a hole injection unit disposed the gate electrode and allowing holes to be injected into the first semiconductor region.
